(19) United States
(12) Patent Application Publication
(10) Pub. No.: US 2014/0166347 A1
(43) Pub. Date: Jun. 19, 2014

(54) PRINTED CIRCUIT BOARD AND METHOD FOR MANUFACTURING THE SAME

(71) Applicant: SAMSUNG ELECTRO-MECHANICS CO., LTD., Suwon (KR)

(72) Inventors: Yoon Su Kim, Suwon (KR); Sung Han, Suwon (KR); Jin Gu Kim, Suwon (KR); Young Do Kweon, Suwon (KR)

(73) Assignee: SAMSUNG ELECTRO-MECHANICS CO., LTD., Suwon (KR)

(21) Appl. No.: 13/831,720

(22) Filed: Mar. 15, 2013

(30) Foreign Application Priority Data
Dec. 17, 2012 (KR) 10-2012-0147834

(51) Int. Cl. H05K 1/02; H05K 3/00

(52) U.S. Cl. CPC H05K 1/0296; H05K 3/00
USPC 174/257; 174/250; 216/13

(57) ABSTRACT

Disclosed herein is a printed circuit board, including: a base substrate; and a circuit pattern formed on the base substrate, including a conductive filler therein, and having roughness formed on a surface thereof.

### CROSS REFERENCE TO RELATED APPLICATION

This application claims the benefit of Korean Patent Application No. 10-2012-0147834, filed on Dec. 17, 2012, entitled “Printed Circuit Board and Method for Manufacturing the Same”, which is hereby incorporated by reference in its entirety into this application.

### BACKGROUND OF THE INVENTION

1. Technical Field

The present invention relates to a printed circuit board and a method for manufacturing the same.

2. Description of the Related Art

Currently, in accordance with rapid slimness and lightness of products in mobile communication and various electronic fields, various and complicated type fine patterns having ultra-fine pitches are formed on various printed circuit boards and the fine pattern is formed through an interlayer circuit connection using a micro-via on a multi-layer printed circuit board, such that methods for forming an insulating film and a solder resist using complicated and various methods have been proposed.

However, adhesion between the insulating film, the solder resist, and the like, configuring the printed circuit board and a metal, which is an organic material, forming a pattern is deteriorated.

Therefore, according to the prior art, a wet surface treatment scheme has been used in order to improve the adhesion between different kinds of materials as described above. That is, roughness is formed on a pattern surface by etching the pattern surface using acid solution before forming the organic materials such as the insulating film, the solder resist, and the like on the pattern made of the metal.

Although the above-mentioned method helps to improve the adhesion between the different kinds of materials, the roughness is formed by etching the pattern. Therefore, it is difficult to secure a minimum metal thickness due to loss of the pattern, such that the fine pattern is not easily implemented.

Meanwhile, a printed circuit board and a method for manufacturing the same according to the prior art have been disclosed in International Patent Laid-Open Publication No. WO00/003570.

### SUMMARY OF THE INVENTION

The present invention has been made in an effort to provide a printed circuit board having roughness formed on a surface of a pattern without loss of the pattern, and a method for manufacturing the same.

The present invention has been also made in an effort to provide a printed circuit board having minimum open defect and a method for manufacturing the same.

According to a preferred embodiment of the present invention, there is provided a printed circuit board, including: a base substrate; and a circuit pattern formed on the base substrate, including a conductive filler therein, and having roughness formed on a surface thereof

The conductive filler may be any one selected from a group consisting of aluminum (Al), magnesium (Mg), zinc (Zn), tin (Sn), beryllium (Be), and an alloy thereof

The conductive filler may have a diameter in the range of 0.1% or more to below 50% with respect to a width of the circuit pattern.

The conductive filler may have a diameter in the range of 0.1% or more to below 50% with respect to a thickness of the circuit pattern.

The circuit pattern may be made of copper (Cu).

According to another preferred embodiment of the present invention, there is provided a method for manufacturing a printed circuit board, the method including: preparing a base substrate; forming a circuit pattern on the base substrate using ink for circuit pattern formation including a conductive filler; and forming roughness on a surface of the circuit pattern by removing the conductive filler exposed to the surface of the circuit pattern.

The conductive filler may be any one selected from a group consisting of aluminum (Al), magnesium (Mg), zinc (Zn), tin (Sn), beryllium (Be), and an alloy thereof.

The conductive filler may have a diameter in the range of 0.1% or more to below 50% with respect to a width of the circuit pattern.

The conductive filler may have a diameter in the range of 0.1% or more to below 50% with respect to a thickness of the circuit pattern.

The ink for circuit pattern formation may include the conductive filler of 50 wt % or less with respect to the ink for circuit pattern formation.

The ink for circuit pattern formation may be made of copper (Cu).

The forming of the circuit pattern may be performed by discharging the ink for circuit pattern formation on the base substrate by an inkjet process.

The forming of the circuit pattern may include sintering the ink for circuit pattern formation discharged on the base substrate.

The removal of the conductive filler may be performed by an etching process using an etching solution.

The etching solution may be any one selected from potassium hydroxide (KOH), sodium hydroxide (NaOH), and calcium hydroxide (CaOH₂).

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a structure of a printed circuit board according to a preferred embodiment of the present invention, and

FIGS. 2 to 4 are cross-sectional views sequentially showing processes of a method for manufacturing the printed circuit board according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Printed Circuit Board

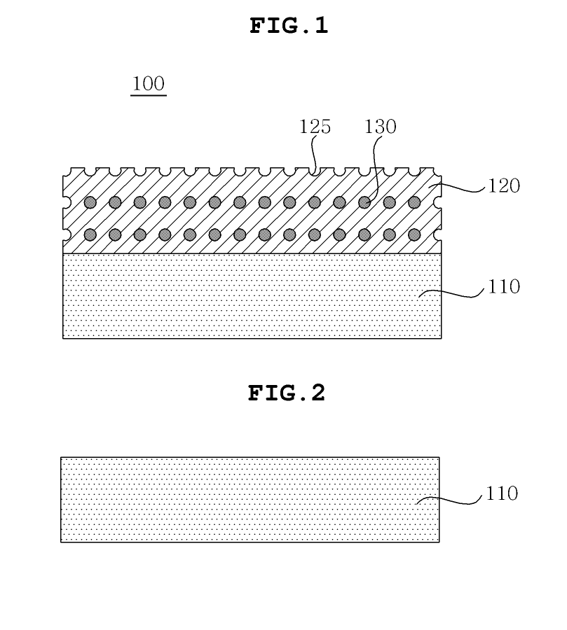

FIG. 1 is a cross-sectional view showing a structure of a printed circuit board according to a preferred embodiment of the present invention.

Referring to FIG. 1, the printed circuit board 100 according to the preferred embodiment of the present invention includes a base substrate 110 and a circuit pattern 120 formed on the base substrate 110, including a conductive filler 130 therein, and having roughness 125 formed on a surface thereof.

According to the preferred embodiment of the present invention, as shown in FIG. 1, the base substrate 110 may be made of only an insulating material but is not specifically limited thereto.

For example, although a configuration of a specific inner layer circuit of the base substrate 110 is omitted in FIG. 1 for convenience of explanation, it may be easily appreciated by those skilled in the art that a general printed circuit board having at least one layer circuit formed on an insulating layer may be used as the base substrate 110.

As the insulating material, a resin insulating material may be used. As the resin insulating material, a thermo-setting resin such as an epoxy resin, a thermo-plastic resin such as a polyimide resin, a resin having a reinforcement material such as a glass fiber or an inorganic filler impregnated therein, for example, a prepreg may be used. In addition, a thermo-setting resin, a photo-setting resin, and the like, may be used. However, the materials of the resin insulating layer are not specifically limited thereto.

Although the FIG. 1 shows a case in which the circuit pattern 120 is formed on only one surface of the base substrate 110, this is only an example. That is, the circuit pattern 120 may also be formed on both surfaces of the base substrate 110.

According to the present embodiment, the circuit pattern 120 may be made of copper (Cu), but is not particularly limited thereto.

In addition, according to the present embodiment, the circuit pattern 120 may include a conductive filler 130 therein.

Here, the conductive filler 130 may be made of any one selected from a group consisting of aluminum (Al), magnesium (Mg), zinc (Zn), tin (Sn), beryllium (Be), and an alloy thereof, but is not particularly limited thereto. For example, the conductive filler 130 may be made of any conductive material capable of being removed by the etching solution which does not damage to copper (Cu) forming the circuit pattern 120.

In addition, according to the present embodiment, the conductive filler 130 may be formed so as to have a diameter in the range of 0.1% or more to below 50% with respect to a width and a thickness of the circuit pattern 120, respectively, but is not particularly limited thereto.

However, in the case in which the diameter of the conductive filler 130 is below 0.1%, the conductive filler 130 becomes an alloy level having an atomic unit and is not selectively etched, such that the roughness may be not almost formed on the surface of the circuit pattern 120.

In addition, in the case in which the diameter of the conductive filler 130 exceeds 50%, the conductive filler 130 is etched, such that the circuit pattern 120 is lost. Therefore, electrical reliability may be decreased.

In addition, according to the present embodiment, the surface of the circuit pattern 120 may be provided with the roughness 125 as shown in FIG. 1.

The roughness 125 is formed by the conductive filler 130 exposed to the surface of the circuit pattern 120 after forming the circuit pattern 120 and a description thereof will be described in detail in a method for manufacturing a printed circuit board.

Method for Manufacturing Printed Circuit Board

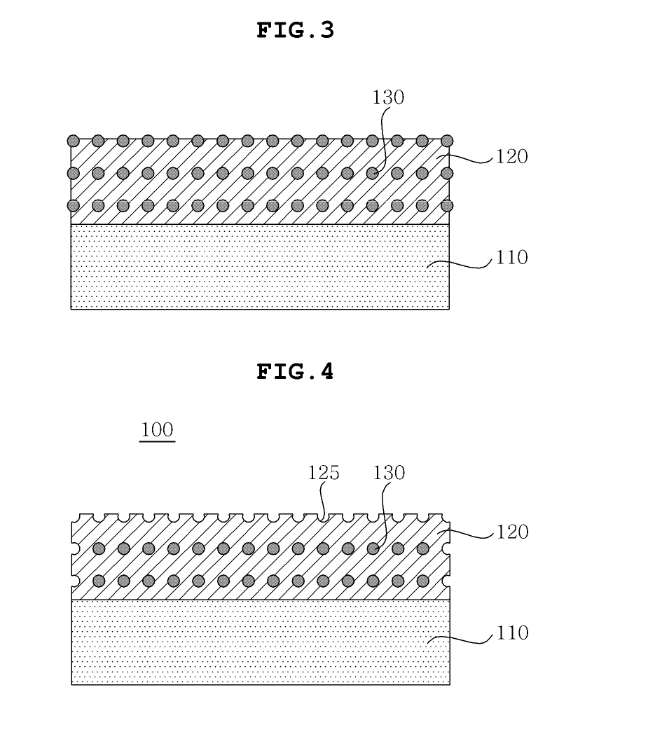

FIGS. 2 to 4 are cross-sectional views sequentially showing processes of a method for manufacturing the printed circuit board according to the preferred embodiment of the present invention.

Referring to FIG. 2, the base substrate 110 is prepared.

According to the present embodiment, the base substrate 110 may be made of only an insulating material as shown in FIG. 2 but is not particularly limited thereto, and it may be easily appreciated by those skilled in the art that a general printed circuit board having at least one layer circuit formed on an insulating layer may be used as the base substrate 110. Here, as the insulating material, a resin insulating material may be used. As the resin insulating material, a thermo-setting resin such as an epoxy resin, a thermo-plastic resin such as a polyimide resin, a resin having a reinforcement material such as a glass fiber or an inorganic filler impregnated therein, for example, a prepreg may be used. In addition, a thermo-setting resin, a photo-setting resin, and the like, may be used. However, the materials of the resin insulating layer are not specifically limited thereto.

Next, referring to FIG. 3, the circuit pattern 120 is formed on the base substrate 110.

In this case, although the FIG. 3 shows a case in which the circuit pattern 120 is formed on only one surface of the base substrate 110, this is only an example and the present invention is not limited thereto. That is, the circuit pattern 120 may also be formed on both surfaces of the base substrate 110.

According to the present embodiment, the circuit pattern 120 may be formed using ink for circuit pattern formation including the conductive filler 130. In this case, according to the present embodiment, the circuit pattern 120 may be formed by discharging the ink for circuit pattern formation on the base substrate 110 by an inkjet process, but is not particularly limited thereto.

As an example, the circuit pattern 120 may also be formed using a screen print scheme using a mask and a squeegee.

The ink for circuit pattern formation may be made of copper (Cu), but is not particularly limited thereto.

In addition, the conductive filler 130 included in the ink for circuit pattern formation may be any one selected from a group consisting of aluminum (Al), magnesium (Mg), zinc (Zn), tin (Sn), beryllium (Be), and an alloy thereof but is not particularly limited thereto. For example, the conductive filler 130 may be made of any conductive material capable of being removed by the etching solution which does not damage to copper (Cu) forming the circuit pattern 120 in a subsequent process.

Here, the ink for circuit pattern formation may include the conductive filler 130 of 50 wt % or less with respect to the ink for circuit pattern formation but is not particularly limited thereto.

However, in the case in which the conductive filler 130 is included in the ink for circuit pattern formation so as to exceed 50 wt %, the roughness of the surface of the circuit pattern 120 may be decreased.

In general, as shown in FIG. 4, in order to form the roughness having a predetermined level or more on the surface of the circuit pattern 120, the conductive fillers 130 dispersed on the surface of the circuit pattern 120 should not contact each other. That is, the circuit pattern 120 corresponding to the diameter of the conductive filler 130 should exist between the conductive filler 130 and an adjacent conductive filler 130 without being lost. Therefore, a bended surface may be formed.

However, in the case in which the ink for circuit pattern formation includes the conductive filler 130 exceeding 50 wt %, the conductive fillers 130 is not appropriately dispersed, such that the conductive fillers 130 contacting each other may be generated. Here, in the case in which the conductive fillers 130 contacting each other is removed by the etching process, the circuit pattern 120 does not exist therebetween, such that the bending is not formed, whereby the roughness is decreased.

In addition, according to the present embodiment, the conductive filler 130 may be formed so as to have a diameter in the range of 0.1% or more to below 50% with respect to a width and a thickness of the circuit pattern 120, respectively, but is not particularly limited thereto.

However, in the case in which the diameter of the conductive filler 130 is below 0.1%, the conductive filler 130 becomes an alloy level having an atomic unit and is not selectively etched, such that the roughness may be not almost formed on the surface of the circuit pattern 120.

In addition, in the case in which the diameter of the conductive filler 130 exceeds 50%, the conductive filler 130 is etched, such that the circuit pattern 120 is lost. Therefore, electrical reliability may be decreased.

As described above, the circuit pattern 120 is formed by performing a sintering process after discharging the ink for circuit pattern formation on the base substrate 110, as shown in FIG. 3. In this case, the conductive filler 130 may be exposed to the surface of the circuit pattern 120 but is not particularly limited thereto.

That is, the conductive fillers 130 may not be exposed to the surface of the circuit pattern 120. In this case, polishing the surface of the circuit pattern 120 to expose the conductive filler 130 may be additionally performed.

Here, the polishing may be a chemical polishing process, a mechanical polishing process, or a chemical-mechanical polishing process, but is not particularly limited thereto.

Next, referring to FIG. 4, the conductive filler 130 exposed to the surface of the circuit pattern 120 is removed to thereby form the roughness 125 on the surface of the circuit pattern 120.

In this case, the removal of the conductive filler 130 may be performed by the etching process using the etching solution, but is not particularly limited thereto.

Here, the etching solution may be any one selected from potassium hydroxide (KOH), sodium hydroxide (NaOH), and calcium hydroxide (CaOH₂), but is not particularly limited thereto. For example, the etching solution may be made of any etching solution which does not etch copper (Cu) forming the circuit pattern 120.

As described above, according to the preferred embodiment of the present invention, the circuit pattern is formed using the ink for forming the circuit pattern including the conductive filler and the conductive filler exposed to the surface of the circuit pattern is then etched and removed, such that the roughness may be formed on the surface of the circuit pattern.

In addition, according to the preferred embodiment of the present invention, only the conductive filler is removed using the etching solution having a property that does not etch the circuit pattern, such that the roughness may be formed on the surface of the circuit pattern without loss of the circuit pattern, thereby making it possible to improve electrical reliability.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a base substrate; and
a circuit pattern formed on the base substrate, including a conductive filler therein, and having roughness formed on a surface thereof.

2. The printed circuit board as set forth in claim 1, wherein the conductive filler is any one selected from a group consisting of aluminum (Al), magnesium (Mg), zinc (Zn), tin (Sn), beryllium (Be), and an alloy thereof.

3. The printed circuit board as set forth in claim 1, wherein the conductive filler has a diameter in the range of 0.1% or more to below 50% with respect to a width of the circuit pattern.

4. The printed circuit board as set forth in claim 1, wherein the conductive filler has a diameter in the range of 0.1% or more to below 50% with respect to a thickness of the circuit pattern.

5. The printed circuit board as set forth in claim 1, wherein the circuit pattern is made of copper (Cu).

6. A method for manufacturing a printed circuit board, the method comprising:
preparing a base substrate;
forming a circuit pattern on the base substrate using ink for circuit pattern formation including a conductive filler; and
forming roughness on a surface of the circuit pattern by removing the conductive filler exposed to the surface of the circuit pattern.

7. The method as set forth in claim 6, wherein the conductive filler is any one selected from a group consisting of aluminum (Al), magnesium (Mg), zinc (Zn), tin (Sn), beryllium (Be), and an alloy thereof.

8. The method as set forth in claim 6, wherein the conductive filler has a diameter in the range of 0.1% or more to below 50% with respect to a width of the circuit pattern.

9. The method as set forth in claim 6, wherein the conductive filler has a diameter in the range of 0.1% or more to below 50% with respect to a thickness of the circuit pattern.

10. The method as set forth in claim 6, wherein the ink for circuit pattern formation includes the conductive filler of 50 wt % or less with respect to the ink for circuit pattern formation.

11. The method as set forth in claim 6, wherein the ink for circuit pattern formation is made of copper (Cu).

12. The method as set forth in claim 6, wherein the forming of the circuit pattern is performed by discharging the ink for circuit pattern formation on the base substrate by an inkjet process.

13. The method as set forth in claim 12, wherein the forming of the circuit pattern includes sintering the ink for circuit pattern formation discharged on the base substrate.

14. The method as set forth in claim 6, wherein the removal of the conductive filler is performed by an etching process using an etching solution.

15. The method as set forth in claim 14, wherein the etching solution is any one selected from potassium hydroxide (KOH), sodium hydroxide (NaOH), and calcium hydroxide (CaOH₂).
